(19) United States
(12) Patent Application Publication
(10) Pub. No.: US 2024/0055323 A1
(43) Pub. Date: Feb. 15, 2024

(54) SEMICONDUCTOR DEVICE INTERCONNECTS HAVING CONDUCTIVE ANNULUS-STABILIZED THROUGH-SILICON VIAS

(71) Applicant: Micron Technology, Inc., Boise, ID (US)

(72) Inventors: Ren Yuan Huang, Taichung (TW); Kuan Wei Tseng, Taichung (TW); Te Pao, Taichung (TW); Koji Torii, Taichung (TW)

(21) Appl. No.: 17/884,468

(22) Filed: Aug. 9, 2022

(51) Int. Cl. H01L 23/48; H01L 23/00; H01L 21/768

(52) U.S. Cl. CPC H01L 23/481; H01L 24/05; H01L 21/7684; H01L 21/76819; H01L 23/562; H01L 2224/0557

(57) ABSTRACT

A semiconductor device assembly including a through-silicon via (TSV) having an end region protruding from a back side of the substrate, the end region being surrounded by a conductive annulus disposed over the back side of the substrate; a dielectric layer disposed over the back side of the substrate, the dielectric layer having an upper surface flush with an upper surface of the end region of the TSV and flush with an upper surface of the conductive annulus; and a bond pad disposed over and electrically coupled to the end region of the TSV and the conductive annulus.

### TECHNICAL FIELD

The present disclosure generally relates to semiconductor devices, and more particularly relates to semiconductor device interconnects having conductive annulus-stabilized through-silicon vias (TSVs).

### BACKGROUND

Microelectronic devices, such as memory devices, microprocessors, and light emitting diodes, typically include one or more semiconductor dice mounted to a substrate and encased in a protective covering. The semiconductor dice include functional features, such as memory cells, processor circuits, interconnecting circuitry, etc. There are demands to reduce the volume occupied by semiconductor dice and increase the capacity and/or speed of the resulting encapsulated assemblies. To meet these demands, multiple semiconductor dice are often stacked vertically on top of each other to increase the capacity or performance of a microelectronic device within the limited volume on the circuit board or other element to which the semiconductor dice are mounted. In some semiconductor dice stacks, the semiconductor dice are electrically interconnected using TSVs. The TSVs enable the semiconductor dice to be stacked close to each other such that adjacent semiconductor dice are spaced apart from each other by only relatively small vertical distances. This, along with a trend of scaling the dimension of the TSVs, enables higher data transfer rates. Typically, the TSVs are thinned in back side wafer planarization by using a chemical mechanical polishing (CMP) process.

### BRIEF DESCRIPTION OF THE DRAWINGS

FIG. 1 depicts a cross-sectional view of a semiconductor device at a stage of back side TSV planarization by using a CMP process.

FIG. 2A-2I depict cross-sectional views of a semiconductor device at various fabrication steps according to embodiments of the invention.

FIG. 3A-3C depict a cross-sectional view and plain views of a semiconductor device assembly according to embodiments of the invention.

FIG. 4 is a flow chart illustrating a method of back side TSV planarization according to embodiments of the invention.

FIG. 5 is a flow chart illustrating a method of forming a conductive layer over and around protruding end region of the TSV according to embodiments of the invention.

FIG. 6 is a schematic view of a system that includes a semiconductor device configured according to embodiments of the invention.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

3D semiconductor device integration including die to die, die to wafter, and wafer to wafer bonding enables Moore's law continuation to obtain smaller and faster semiconductor devices. The scaling of TSV pitches and individual TSV dimensions in the semiconductor device assemblies enables high-density interconnects between two or more vertically-stacked semiconductor devices for different applications. The fabrication of TSVs involves etching a deep hole into a semiconductor wafer or substrate and filling the resulting hole with a conductive material such as copper. The semiconductor wafer is then thinned from its back side until the TSVs are exposed, and then the exposed TSVs are planarized and have bond pads formed thereon for electrical interconnections. Typically, the back side TSV planarization is conducted using a CMP process in order to expose an end region of the TSVs for bond pad connection.

As TSVs being designed with even smaller dimensions, one challenge of using a CMP process to expose TSVs on back side of a wafer is that the CMP process may fail to achieve a required process yield due to TSV toppling issues. The toppled TSV may act as residual material that interferes with the electrical contact among the TSVs and cause electrical shorts. Further, the damaged TSVs during back side planarization may cause electrical disconnections between stacked semiconductor devices.

To address these drawbacks and others, embodiments of the present technology provide semiconductor device interconnects that stabilize an exposed end region of a TSV with a conductive annulus. The conductive annulus surrounds the protruding end region of the TSV in a horizontal plane, providing mechanical support to the exposed end region during a polishing operation to planarize the end region and a dielectric material disposed at the back side of the semiconductor device. As a result, the TSV is more resistant to toppling and the yields of back side TSV planarization can be significantly improved. Further, the annulus-stabilized end region can enhance a mechanical strength of a bond pad formed over the annulus and the end region of the TSV. The bond pad can be disposed on the planarized upper surfaces of the end region of the TSV and the conductive annulus, overhanging the polished surface of the dielectric material.

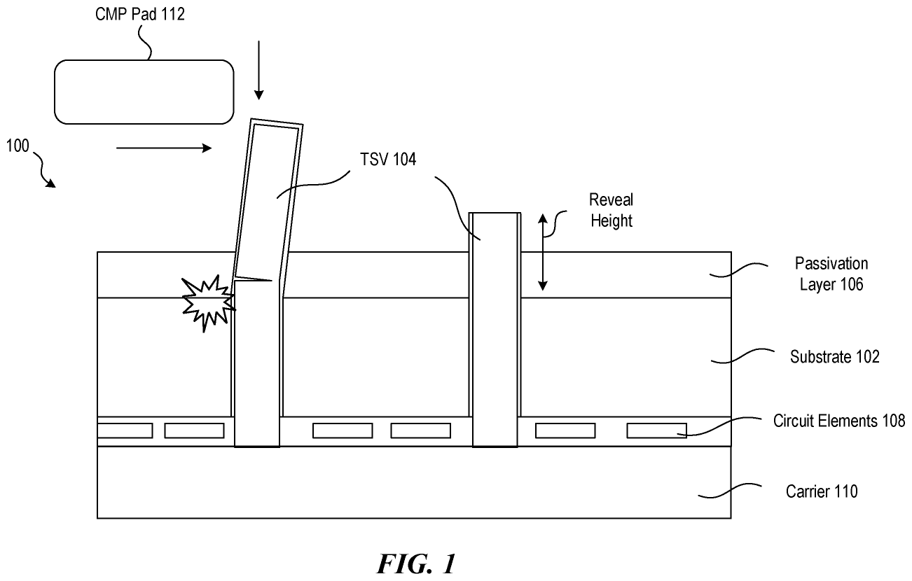

FIG. 1 depicts a cross-sectional view of a semiconductor device 100 at a stage of a back side TSV planarization process. As shown, a substrate 102 can include a silicon substrate (e.g., a silicon die or a silicon wafer) and a plurality of circuit elements 108 (e.g., active semiconductive devices, wires, traces, interconnects, etc.) in or at the front side of the substrate 102. The TSVs 104 include a conductive fill and a barrier material disposed between the conductive fill and the surrounding substrate 102. The TSVs 104 may be formed in a via-first approach, in which a wafer back side thinning process (e.g., by etching or grinding) can be conducted after the formation of the TSVs, to reveal the TSVs 104 from the backside of the substrate 102 using a wafer grinding or lapping tool. The TSVs 104 may have a reveal height above the back side of the substrate 102 ranging from 5 um to 20 um and a diameter ranging from 2 um to 5 um. The semiconductor device 100 can be attached on a carrier 100, e.g., a silicon wafer, for the back side TSV planarization process.

The back side TSV planarization can be conducted by a CMP process to expose the end region of the TSVs 104 for electrical interconnection. In addition, the CMP process may include contacting a polishing pad 112 and optionally a polishing liquid with the backside of the substrate 102. The CMP process may also include applying both a vertical force from the polishing pad to the backside of the substrate 102 and a lateral force caused by moving the substrate 102 and the polishing pad relative to each other. At least a portion of the TSVs 104 is removed from its protruding end region during the CMP process.

As described, the CMP process applies a vertical force and a lateral force on the protruding TSV during the back side planarization. As the dimension of the TSVs 104, e.g., its radius, is scaled down, the protruding TSVs 104 becomes more easy to topple due to the lateral forces of the CMP process. For example, as shown in FIG. 1, the TSVs 104 may break at the back side surface of the substrate 102, because the passivation layer 106 cannot provide enough mechanical support to the TSV 104 during the back side planarization. As a result, the CMP process yields may be significantly reduced as the TSV dimensions (e.g., radius of TSV) are scaled down.

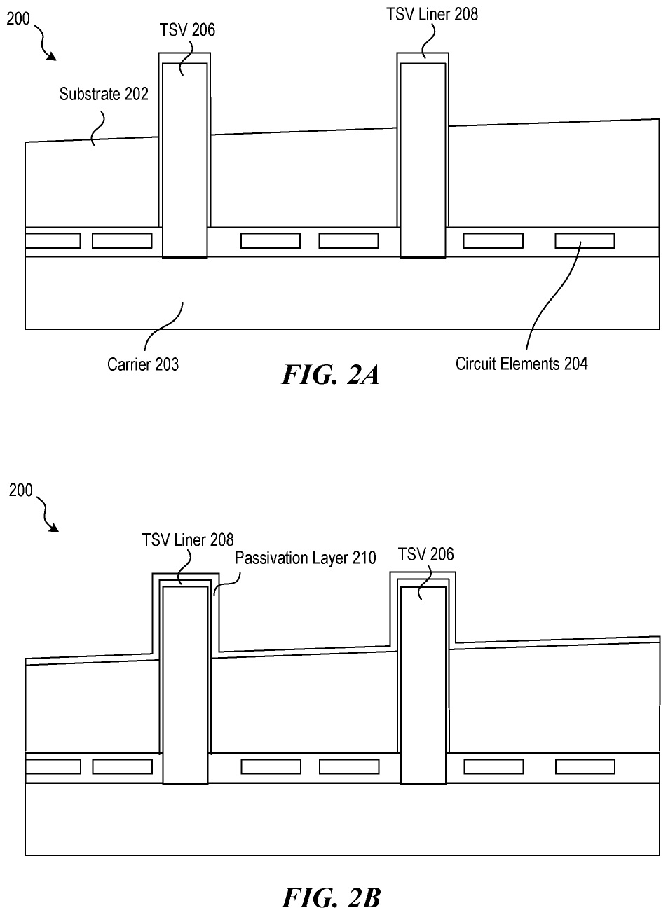

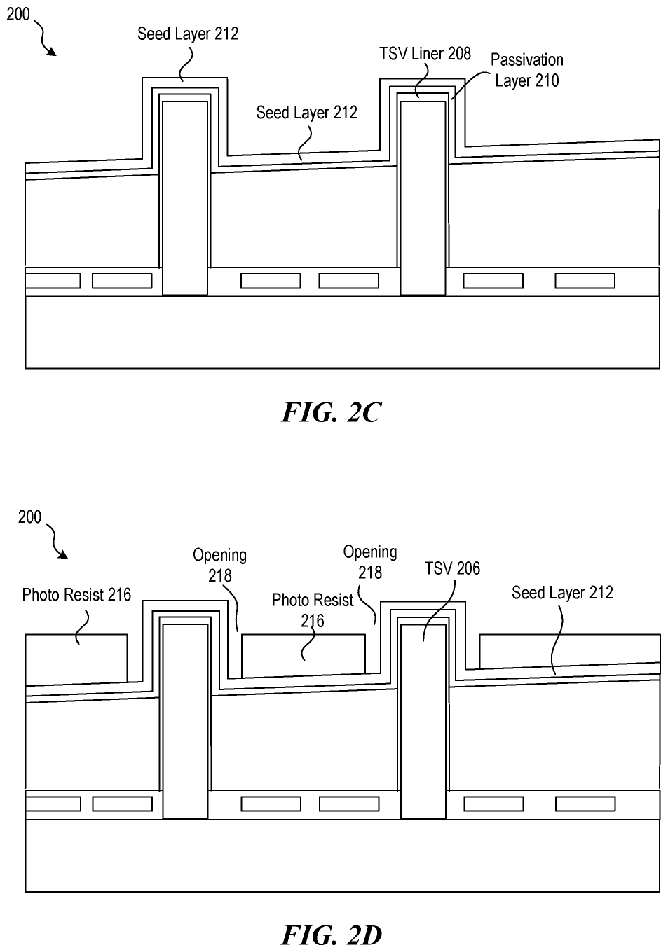

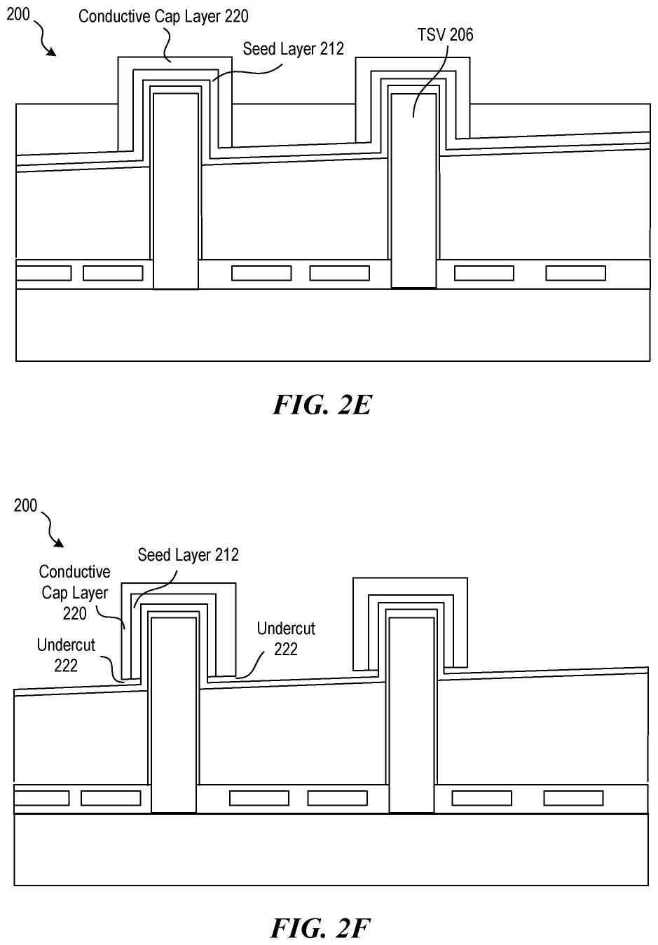

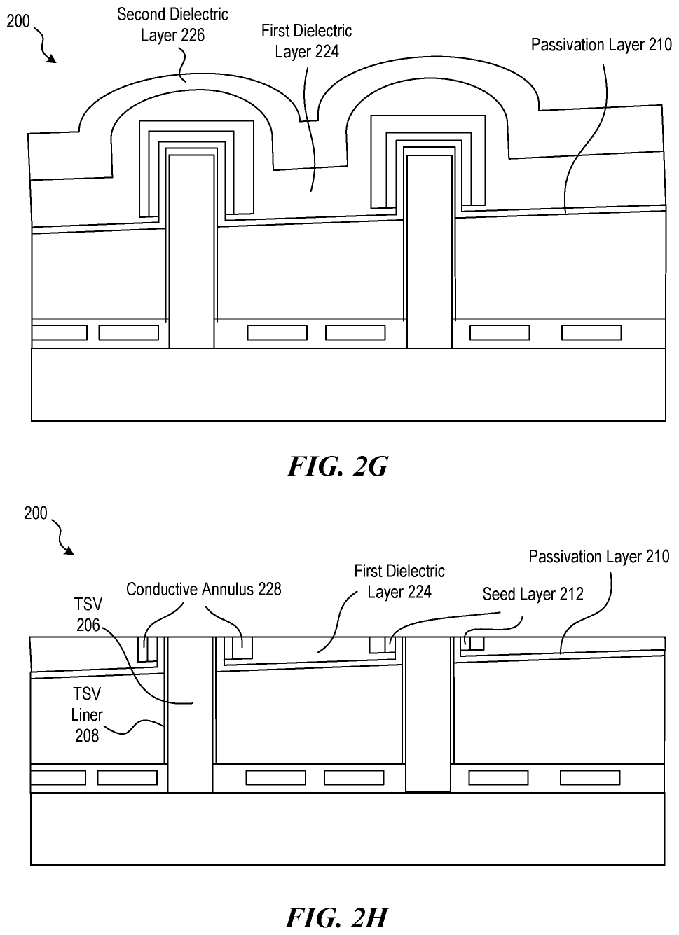

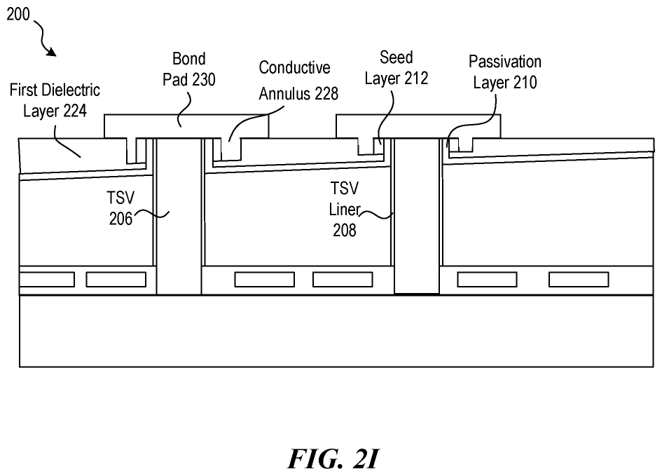

FIG. 2A-2I are cross-sectional views of a semiconductor device 200 at various fabrication steps for back side TSV planarization according to embodiments of the invention. With reference to FIG. 2A, the semiconductor device 200 includes the TSVs 206 formed in a substrate 202 and revealed by an earlier process of substrate thinning. The substrate 202 can include a silicon substrate and a plurality of circuit elements 204 disposed in or at a front side of the substrate 202. In addition, the semiconductor device 200 may be attached on a carrier 203, e.g., a silicon wafer, for the back side TSV planarization process. After thinning the substrate 202, an end portion of the TSV 206 as well as a portion of the TSV liner 208 may protrude from the back side of the substrate 202. In some embodiments and as shown, the back side surface of the substrate 202 may not be planarized after the back side etching or griding process.

FIG. 2B shows the semiconductor device 200 after a passivation layer 210 has been deposited over the back side of the substrate 202. Specifically, the passivation layer 210 can be conformally coated on the protruded region including sidewall and top surface of the TSV 206. The deposition of the passivation layer 210 may be conducted by any appropriate techniques including, chemical vapor deposition (CVD), physical vapor deposition (PVD), atomic layer deposition (ALD), or gas cluster ion beam (GCIB) deposition. In this example, the passivation liner 210 may be an insulating dielectric material, e.g., tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. In some embodiments, the passivation layer 210 may have a thickness ranging from 20 nm to 500 nm.

FIG. 2C shows the semiconductor device 200 after a seed layer 212 has been deposited over the back side of the substrate 202. The seed layer material can be selected to allow plating of a metal thereon to form a conformal coating on the protruding TSV 206 and the passivation layer 210. In some embodiments, the seed layer 212 can be a copper or other metallic material deposited via sputtering, atomic material deposition, chemical vapor deposition, or other suitable technique. In some embodiments, the seed layer 212 can have a thickness ranging from 10 nm to 500 nm.

FIG. 2D shows the semiconductor device 200 after a photoresist layer 216 has been coated and patterned over the seed layer 212, with openings 218 exposing the protruding TSVs 206. The coated photo resist 216 may have a thickness less than the height of the protruding TSV 206. As shown, the photo resist 216 can be patterned using photolithography and development of the photoresist, followed by wet or dry chemical etching, or other suitable material removal technique. The patterned photo resist 216 covers portions of the seed layer 212 between the TSVs 206 and exposes those portions of the seed layer 212 that surround the protruding end region of the TSVs 206. There may be openings 218 that surrounds the TSV 206 and that have a round planar shape in a horizontal plane. In other embodiments, the photo resist 216 may be patterned with openings 218 in other shapes, such as triangular, square, or other regular or irregular polygonal shapes. The openings 218 may be sized such that a gap between the photo resist 216 and the seed layer 212 vertically coated on the sidewall of protruding TSV 206 extends from about 100 nm to about 1 um.

FIG. 2E shows the semiconductor device 200 after a conductive cap layer 220 has been deposited on the exposed portions of the seed layer 212 surrounding each protruding TSV 206. Specifically, the conductive cap layer 220 may be formed by electroplating or electroless plating on the exposed portion of the seed layer 212. As shown, the conductive cap layer 220 can be conformally coated above a top surface and along the sidewall of the protruding TSVs 206. In some embodiments, the conductive cap material deposition continues until it completely fills the gaps between the photo resist 216 and the seed layer 212 vertically coated on the sidewall of protruding TSV 206 (e.g., until a thickness of the conductive cap layer 220 on the sidewall of the protruding TSV 206 corresponds to the gap). The conductive cap layer 220 can include copper and in some embodiments may be the same material as the conductive fill material of the TSVs 206. In some embodiments, the conductive cap layer 220 has a circular shape in the horizontal plane, corresponding to the circular shape of the openings 218 in the photo resist 216. In other embodiments, the conductive cap layer may have a triangular shape, a square shape, or another regular or irregular polygonal shape in the horizontal plane that corresponds to the various other possible shapes of the openings 218 in the photo resist 216.

FIG. 2F shows the semiconductor device 200 after the photo resist 216 has been stripped and the seed layer 212 disposing on the back side of the substrate 202 has been removed. The photo resist 216 can be stripped by using photo resist stripper. In some embodiments, the photo resist removal can be done by a combination of plasma resist strip to remove a majority of the resist followed by a wet cleaning process to remove remaining organic residue on the back side of the substrate 202. In this embodiment, the seed layer 212 disposed under the patterned photo resist 216 can be further removed by an isotropic wet etching process. Specifically, the removal of the seed layer 212 may cause an undercut 222 below the conductive cap layer 220 and the seed layer 212 that are vertically disposed on the sidewall of each of the protruding TSVs 206. The undercut region 222 may extend partially or completely under the conductive cap layer 220 and may further extend partially or completely under the seed layer 212.

FIG. 2G shows the semiconductor device 200 after multiple layers of dielectric have been deposited on the back side of the substrate 202. As shown, a first dielectric layer 224 can be deposited over the passivation layer 210 between the TSVs 206 and over the protruding end regions of the TSVs 206. In some embodiments, the first dielectric layer 224 fills in the undercuts 222 and extends below the conductive cap layers 220 and the remaining portion of the seed layer 212 disposed on the sidewall of TSVs 206. A second dielectric layer 226 can be further deposited on the first dielectric layer 224. According to one aspect of the present technology, the first dielectric layer 224 may have an upper surface that extends higher along the conductive cap layer 220 than an eventual finished back surface of the semiconductor device 200. The deposition of the multiple dielectric layers 224 and 226 may be conducted by any appropriate techniques including CVD, PVD, and/or spin-coating techniques. In this example, the first and second dielectric layers 224 and 226 may be made of materials including TEOS, silicon oxide, silicon nitride, silicon oxycarbide (SiOC), or a combination thereof. In some embodiments, the first dielectric layer 224 may be made of silicon nitride and the second dielectric layer 226 may be made of silicon oxide. In some embodiments, the second dielectric layer 226 may have a polishing resistance lower than that of the first dielectric layer 224.

FIG. 2H shows the semiconductor device 200 after its back side has been planarized, for example, by a CMP process. In some embodiments, the CMP process can remove materials from the back side of the substrate 202, including the second dielectric layer 226 and a portion of the first dielectric layer 224. Further, the CMP process can additionally remove a portion of the conductive cap layer 220 to form a conductive annulus 228 surrounding the protruding end portion of the TSV 206. Further, as can be seen with reference to FIG. 2H, the CMP process can remove portions of the seed layer 212, the passivation layer 210, and the TSV liner 208. The protruding TSVs 206 can be reduced in height via the CMP process and expose a back side surface that is planar and parallel to a front side surface of the substrate 202. As shown, the first dielectric layer 224, the conductive annulus 228, the seed layer 212, the passivation layer 210, and the TSV liner 208 are all substantially coplanar with the exposed back side surface of the TSVs 206, after the back side TSV planarization. According to one aspect of the present technology, the presence of the first dielectric layer 224 during the CMP process improves planarity at the back side of the substrate 202.

Notably, the conductive annulus 228 provides a much greater amount of contact with the first dielectric layer 224 than would the TSVs 206 alone, providing greatly improved mechanical stability for the TSVs 206 during the back side TSV planarization.

Following the back side planarization, as shown in FIG. 2I, a bond pad 230 can be formed over each of the TSVs 206. The bond pad 230 can be fabricated by plating conductive material on patterned openings of a hard mask layer on the planarized back side of the substrate 202, the hard mask openings being disposed above the protruding end regions of the TSVs 206. In an example embodiment, a single bond pad 230 can be connected by a single TSV 206 for electrical interconnections between stacking semiconductor devices. In addition, the bond pad 230 can be disposed on the planarized conductive annulus 228 and overhang the polished surface of the first dielectric layer 224. In this example, the bond pad 230 is in contact with the TSV 230, the TSV liner 208, the passivation layer 210, the seed layer 212, and the conductive annulus 228, therefore presenting an improved mechanical strength due to increased contact area of the conductive annulus 228.

In some embodiments, the semiconductor device 200 assembly further includes stacking a plurality of semiconductor devices to form a three-dimensional (3D) device assembly. For example, after the semiconductor 200 devices are formed, they can be “stacked” to couple an interconnect (e.g., solder bump) of a first semiconductor device to a bond pad of a second semiconductor device. Conventional processes for packaging the stacked semiconductor dice include electrically coupling the stacked semiconductor dice 200 through the interconnected bond pads 230 and solder bumps through the TSVs 206 penetrating the stacked semiconductor dice and encapsulating the stacked semiconductor dice to protect them from environmental factors (e.g., moisture, particulates, static electricity, and physical impact).

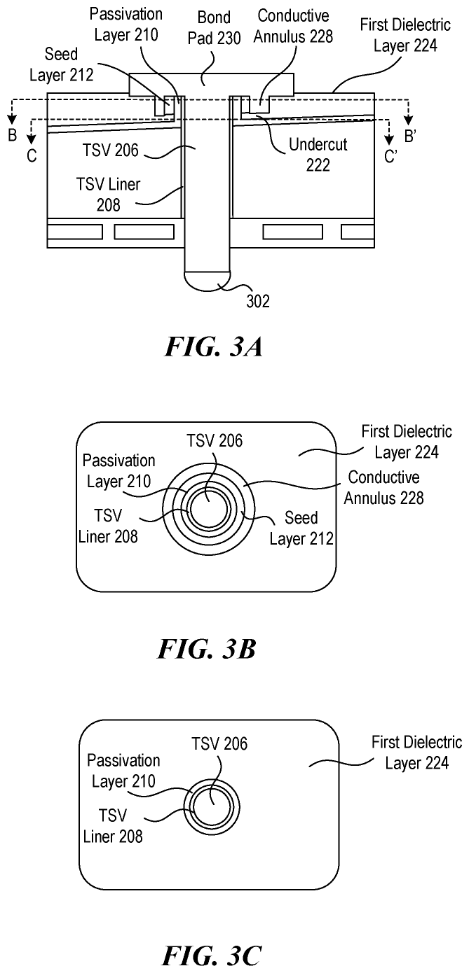

Turning to FIGS. 3A-3C, which illustrate the assembled semiconductor device 200 in cross sectional view and plane views. FIG. 3A shows a cross sectional view of semiconductor device 200 assembly after the back side TSV planarization and bond pad formation. FIGS. 3B and 3C show plane views of the semiconductor device 200 assembly through the B-B′ plane and the C-C′ plane, respectively.

As shown in FIG. 3A, the back side of the TSV 206 is co-planarized with the first dielectric layer 224, the conductive annulus 228, the seed layer 212, and the passivation layer 210 in a CMP process on the back side of the substrate 202. In some embodiments, the bond pad 230 may be further fabricated on the back side of the semiconductor device 200 and is electrically connected with the protruding end region of the TSV 206. In addition, the bond pad 230 partially overhang the mechanically altered surface of the first dielectric layer 224. Further, the bond pad 230 is in contact with the conductive annulus 228 and reveals a strengthened mechanical support thereon.

FIG. 3B shows the plane view of the planar surface of the semiconductor device 200 assembly through the B-B′ plane, which locates below the bond pad 230 and above the undercut 222. In particular, the B-B′ plane passes through the protruding end region of the TSV 206. In one embodiment and as shown in FIG. 3B, the protruding TSV 206 is co-planarized with the TSV liner 208, the passivation layer 210, the seed layer 212, and the conductive annulus 228 after the back side planarization CMP process. The B-B′ plane is further filled by the first dielectric layer 224 which has a mechanically altered surface after the CMP process. In this example, the conductive annulus 228 is much wider than the TSV 206. As a result, the conductive annulus 228, the seed layer 212, and the passivation layer 210, all contribute to a larger plane feature surrounding the protruding end portion of the TSV 206, providing a stronger mechanical support to the TSV 206 in the back side TSV planarization and avoiding TSV toppling.

FIG. 3C shows the plane view of the planar surface of the semiconductor device 200 assembly through the C-C′ plane, which is disposed through the first dielectric 224 and the undercut 222. As described earlier, the undercut 222 is formed during the etching of a portion of the seed layer 212 that is disposed on the back side surface of the substrate 202. Specifically, the first dielectric layer 224 then fills into the undercut 222 during the dielectric deposition process and is located under at least partially the conductive annulus 228 and the seed layer 212 that are vertically aligned on the sidewall of each of the protruding TSVs 206. As shown in FIG. 3C and along the C-C′ plane, the first dielectric layer 224 surrounds the passivation layer 210 as well as the TSV liner 208, both being disposed on the sidewall of the protruding end portion of the TSV 206.

In some embodiments, a pad pattern shown in FIG. 3B and across the B-B′ plane, including the conductive annulus 228, the seed layer 212, and the passivation layer 210, can be in a circular shape. For example, the TSV 206 can be fabricated in a circular shape in the horizontal plane by etching a circular hole within the substrate 202. Thereafter, the seed layer 212, the passivation layer 210, and the conductive cap layer 220 can all be coated conformally on the protruding end region of TSV 206 in the circular shape. The conductive annulus 228 is further transferred from the conductive cap layer 220 during back side TSV planarization process described in FIG. 2H. In this example, the first pad pattern, defined by an outer edge of the conductive annulus 228 through the B-B′ plane, can be in a circular shape.

In some other embodiments, the pad pattern including the conductive annulus 228, the seed layer 212, and the passivation layer 210 can be in a square shape. For example, the photo resist patterning process described in FIG. 2D may form the opening 218 between the patterned photo resist 216 and the seed layer 212 disposed on sidewall of the TSV 206 into a square shape across the B-B′ plane. The following conductive cap layer 220 deposition process can continually fills conductive cap material into the opening 218. Correspondingly, the outer edge of the conductive annulus across the B-B′ plane can be in a square shape and defines the first pad pattern to be the same. In some other embodiments, the pad pattern can be configured in other shapes including triangle or another regular or irregular polygonal shapes.

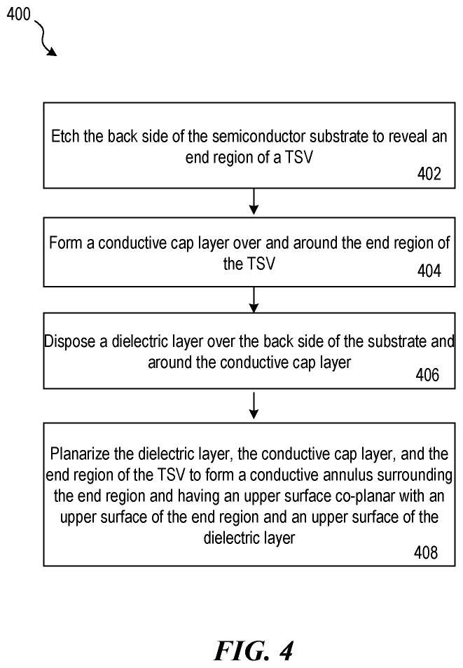

FIG. 4 is a flow chart illustrating a method 400 of back side TSV planarization of semiconductor device assembly by a CMP process with widened process window. Referring to FIGS. 1-3, the method 400 includes etching a back side of a semiconductor substrate to reveal an end region of a TSV, at 402. For example, TSVs 206 can be formed in a substrate 202 and revealed by an earlier process of substrate thinning. There is a protruding end region of TSVs 206 revealed on the back side of the semiconductor substrate 202.

The method 400 also includes forming a conductive cap layer over and around the end region of the TSV, at 404. For example, the conductive cap 220 can be conformally coated by electroplating or electroless plating techniques over the protruding end region of the TSVs 206.

Further, the method 400 includes disposing a dielectric layer over the back side of the substrate and around the conductive cap layer, at 406. For example, the first dielectric layer 224 and the second dielectric layer 226 can be sequentially coated on the back side of the substrate 202 so as to fill the regions between the protruding end regions of the TSVs 206. In addition, the dielectric layers 224 and 226 are coated around the conductive cap layer 220. The deposition of the multiple dielectric layers 224 and 226 may be conducted by any appropriate techniques including CVD, PVD, and/or spin-coating techniques.

Lastly, the method 400 includes planarizing the dielectric layer, the conductive cap layer, and the end region of the TSV to form a conductive annulus surrounding the end region and having an upper surface co-planar with an upper surface of the end region and an upper surface of the dielectric layer, at 408. For example, a CMP process can be implemented on planarizing the first and second dielectric layers 224 and 226, the conductive cap layer 220, and the protruding end region of the TSV 206. Specifically, the CMP process can remove a portion of the conductive cap layer 220 to form the conductive annulus 228 as shown in FIG. 2H. In addition, the CMP process polishes the protruding end portion of the TSV 206 and the first dielectric layer 224 to form a mechanical altered surface thereon. The conductive annulus 228 and the polished dielectric layer 224 are all substantially coplanar with the exposed back side surface of the protruding end region of the TSV 206, and provide greatly improved mechanical stability to the TSVs 206 during the back side TSV planarization.

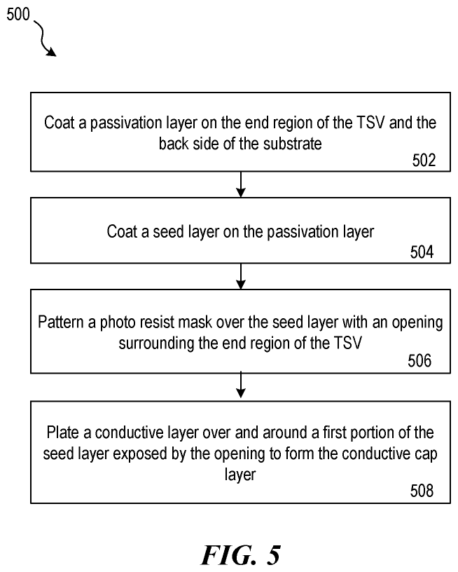

Turning now to FIG. 5, a flow chart illustrating a method 500 of forming a conductive cap layer over and around the protruding end region of a TSV. The method 500 includes coating a passivation layer on the end region of the TSV and the back side of the substrate, at 502. For example, the passivation layer 210 can be conformally coated on the protruding end portion of the TSVs 206 on the back side of the substrate 202. Specifically, the passivation layer 202 can also be coated on opening regions of the back side surface of the substrate 202 between the protruding TSVs 206.

The method 500 also includes coating a seed layer on the passivation layer, at 504. For example, the seed layer 212 can be conformally coated above the the passivation layer 210 and over the protruding end portion of the TSV 206 via sputtering or other suitable technique. Further, the seed layer 212 is also coated on the back side surface of the substrate 202.

Further, the method 500 includes patterning a photo resist mask over the seed layer with an opening surrounding the end region of the TSV, at 506. For example, the photo resist layer 216 can be coated on the back side of the substrate 202 and patterned to create the openings 218. The openings 218 surround the protruding end region of the TSVs 206 and can be in an anulus shape in the horizontal plane. In some other embodiments, the opening 218 can be in a different shape including a triangle shape, a square shape, or another regular or irregular polygonal shape.

Lastly, the method 500 includes plating a conductive layer over and around a first portion of the seed layer exposed by the opening to form the conductive cap layer, at 508. For example, the conductive cap layer 220 can be coated on the seed layer 212 by electroplating or electroless plating techniques. Specifically, the conductive cap layer 220 can further fulfill the opening 218 and encapsulate the protruding end region of TSV 206. In the horizontal plane, the shape of the conductive cap layer 220 defines the shape of the conductive annulus that surrounds the protruding end portion of the TSV 206.

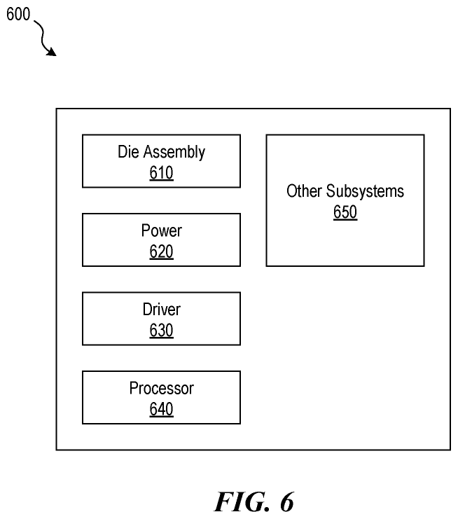

Any one of the semiconductor structures described above with reference to FIGS. 1A-3C can be incorporated into any of a myriad of larger and/or more complex systems, a representative example of which is system 600 shown schematically in FIG. 6. The system 600 can include a semiconductor device 610, a power source 620, a driver 630, a processor 640, and/or other subsystems or components 650. The semiconductor device 610 can include features generally similar to those of the semiconductor devices described above, and can therefore include multi stage pad structures on the back side of substrate to avoid TSV toppling in a back side planarization process. The resulting system 600 can perform any of a wide variety of functions, such as memory storage, data processing, and/or other suitable functions. Accordingly, representative systems 600 can include, without limitation, hand-held devices (e.g., mobile phones, tablets, digital readers, and digital audio players), computers, and appliances. Components of the system 600 may be housed in a single unit or distributed over multiple, interconnected units (e.g., through a communications network). The components of the system 600 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a through-silicon via (TSV) having an end region protruding from a back side of the substrate, the end region being surrounded by a conductive annulus disposed over the back side of the substrate;
a dielectric layer disposed over the back side of the substrate, the dielectric layer having an upper surface flush with an upper surface of the end region of the TSV and flush with an upper surface of the conductive annulus; and
a bond pad disposed over and electrically coupled to the end region of the TSV and the conductive annulus.

2. The semiconductor device assembly of claim 1, wherein the bond pad at least partially overhangs the dielectric layer.

3. The semiconductor device assembly of claim 1, wherein the upper surface of the dielectric layer is a mechanically altered surface.

4. The semiconductor device assembly of claim 1, wherein the conductive annulus, a TSV liner, a passivation layer, and/or a seed layer are vertically aligned on a sidewall of the protruding end region of the TSV.

5. The semiconductor device assembly of claim 4, wherein the passivation layer further extends on the back side of the substrate.

6. The semiconductor device assembly of claim 4, wherein the bond pad is disposed over and electrically coupled to the TSV liner and the seed layer.

7. The semiconductor device assembly of claim 4, wherein the dielectric layer is disposed on the passivation layer extending on the back side of the substrate, the dielectric layer having a region disposed under the seed layer and/or the conductive annulus.

8. The semiconductor device assembly of claim 4, wherein the passivation layer is made of at least one of tetraethyl orthosilicate (TEOS) or silicon nitride.

9. The semiconductor device assembly of claim 4, wherein the seed layer and/or the conductive annulus are made of at least one of copper, tungsten, molybdenum, nickel, titanium, tantalum, platinum, silver, gold, ruthenium, iridium, rhenium, rhodium, or alloys thereof.

10. The semiconductor device assembly of claim 4, wherein the passivation layer is made of at least one of silicon oxide, silicon nitride, silicon oxycarbide, silicon oxycarbonitride, or silicon carbon nitride.

11. An apparatus, comprising:
a through-silicon via (TSV) having an end region protruding from a back side of a substrate;
a conductive annulus that surrounds the end region of the TSV and that is separated from the end region of the TSV by a first dielectric material;
a layer of a second dielectric material having a mechanically altered surface, the layer of second dielectric material being disposed over the back side of the substrate and surrounding the conductive annulus; and
a bond pad disposed over the end region of the TSV and the conductive annulus, the bond pad at least partially overhanging the mechanically altered surface of the layer of second dielectric material.

12. The apparatus of claim 11, wherein the first dielectric material extends over the back side of the substrate.

13. The apparatus of claim 11, further comprising a seed layer disposed between the conductive annulus and the first dielectric material.

14. The apparatus of claim 13, wherein a portion of the first dielectric material, the seed layer, and the conductive annulus are conformally disposed on a sidewall of the protruding end region of the TSV.

15. The apparatus of claim 13, wherein the layer of second dielectric material extends between a bottom surface of the conductive annulus and the first dielectric material, and wherein the layer of second dielectric material extends between a bottom surface of the seed layer and the first dielectric material.

16. A method of forming an interconnect at a back side of a semiconductor substrate, the method comprising:
etching the back side of the semiconductor substrate to reveal an end region of a through-silicon via (TSV);
forming a conductive cap layer over and around the end region of the TSV;
disposing a dielectric layer over the back side of the substrate and around the conductive cap layer; and
planarizing the dielectric layer, the conductive cap layer, and the end region of the TSV to form a conductive annulus surrounding the end region and having an upper surface co-planar with an upper surface of the end region and an upper surface of the dielectric layer.

17. The method of claim 16, further comprising:
coating a passivation layer on the end region of the TSV and the back side of the substrate;
coating a seed layer on the passivation layer;
patterning a photo resist mask over the seed layer with an opening surrounding the end region of the TSV; and
plating a conductive layer over and around a first portion of the seed layer exposed by the opening to form the conductive cap layer.

18. The method of claim 17, further comprising removing the photo resist mask and etching a second portion of the seed layer that is not covered by the conductive cap.

19. The method of claim 17, wherein the conductive annulus is separated from the end region of the TSV by the passivation layer.

20. The method of claim 16, wherein disposing the dielectric layer comprises coating a first dielectric material over the back side of the substrate, and coating a second dielectric material over the first dielectric material, wherein a top surface of the second dielectric material laterally spaced away from the conductive cap layer is higher than a top surface of the conductive cap layer, and wherein the second dielectric material has a higher chemical mechanical polishing rate comparing to that of the first dielectric material.
